(19) United States
(12) Patent Application Publication
(10) Pub. No.: US 2006/0274595 A1
(43) Pub. Date: Dec. 7, 2006

(54) Apparatus for supplying internal voltage

(76) Inventors: Sang-Jin Byeon, Kyoungki-do (KR); Seok-Cheol Yoon, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/322,949

(22) Filed: Dec. 30, 2005

(30) Foreign Application Priority Data
Jun. 7, 2005 (KR) 2005-0048378

(51) Int. Cl. G11C 5/14

(52) U.S. Cl. 365/226

(57) ABSTRACT

An apparatus for supplying an internal voltage is provided the apparatus for supplying an internal voltage comprises: a comparison unit for comparing a reference voltage with an internal reference voltage to output a driving signal based on the comparison result; an internal voltage providing unit for providing the internal voltage according to the current value of the driving signal; a first biasing unit for providing a first bias current to the comparison unit according to the reference voltage; and a second biasing unit for providing a second bias current to the comparison unit according to a standby operation mode.

### FIELD OF THE INVENTION

The present invention relates to an apparatus for supplying an internal voltage for use in a semiconductor memory device.

### DESCRIPTION OF RELATED ARTS

Generally, in accordance with the demands for high speed, high density and low power in a memory device, a memory device converts an external power into an internal voltage having a lower level than an external power and use for a core voltage, a peripheral voltage, a voltage for delay locked loop (DLL), a bit line pre-charge voltage, and a cell plate voltage.

The memory device generates the internal voltage by converting the external power or pumping charge using the external power.

A method for generating the internal voltage by converting the external power uses a unit gain amplifier with a current mirror and a buffer.

The operation of the memory device should be stably maintained regardless of variations of the external power. The power consumption for operating the memory device is reduced by providing the current needed during a standby mode and an active mode of the memory device using the internal voltage above.

That is, it is advantageous to use the internal voltage to maintain a predetermined certain level instead of using the external power directly for operation of the memory device as it is, in regard to reliability and power consumption.

Furthermore, the internal voltage may be provided to prepare drivers in regard to an operation mode of the memory device, i.e., standby mode or active mode, to reduce power consumption.

FIG. 1 is a schematic diagram illustrating a conventional apparatus for supplying an internal voltage for use in a memory device.

The conventional apparatus for supplying an internal voltage of the memory device includes: a comparison unit 1; a biasing unit 2; a current control unit 3; a load unit 4; and a capacitor unit 5.

The comparison unit 1 includes an inverter IV1, PMOS transistors P1 to P4 wherein PMOS transistors P2 and P3 form a current mirror, and NMOS transistors N1 and N2. The comparison unit 1 compares a reference voltage VREF with an internal reference voltage Vint_REF to output a driving signal DRV.

The biasing unit 2 connected between the comparison unit 1 and a ground voltage VSS includes an NMOS transistor N3, wherein the reference VREF is inputted at the gate of the NMOS transistor N3. The NMOS transistor N3 is turned on while the reference VREF provides a stable reference voltage in order to control a bias state of the comparison unit 1.

The current control unit 3 includes PMOS transistors P5 to P7 connected in parallel between a supply terminal of an external voltage VDD and an output terminal of an internal voltage Vint, wherein the driving signal DRV is inputted at each gate of the PMOS transistors P5 to P7.

The load unit 4 connected between the output terminal of the internal voltage Vint and a supply terminal of the ground voltage VSS includes PMOS transistors P8 and P9, wherein each gate of PMOS transistors P8 and P9 is connected to each drain of the same for performing an operation as a diode.

Also, the capacitor unit 5 connected between the output terminal of the internal voltage Vint and a supply terminal of the ground voltage VSS includes a first capacitor CP1 made using a PMOS transistor and a second capacitor CN1 made using an NMOS transistor for maintaining the voltage levels of the internal voltage and the internal reference voltage Vint_REF.

A size of the NMOS transistor N3 in a biasing unit 2 with the above described configuration is closely related to an enable characteristic and standby current consumption of the comparison unit 1.

Because the internal voltage is used periodically in the semiconductor memory device, there is a periodic current consumption by the apparatus used to supply the internal voltage. Therefore, the voltage level of internal voltage being outputted to the output node (A) fluctuates.

It is important to recover the voltage level of internal voltage back to the original level as fast as possible. If the voltage level of the internal voltage is not quickly recovered, the semiconductor memory device using the internal voltage may not operate stably.

Thus, to supply the stable voltage level of the internal voltage, the size of the NMOS transistor N3 in a biasing unit 2 must be increased sufficiently.

However, as the size of the NMOS transistor N3 in a biasing unit 2 become larger, an amount of the current flowing in the NMOS transistor N3 is increased to thereby increase standby current of the apparatus for supplying an internal voltage.

Therefore, there is a limitation that the conventional apparatus unnecessarily consumes a large amount of current when the amount of current required for stably generating the internal voltage is very small, e.g., during a self refresh mode.

### SUMMARY OF THE INVENTION

It is, therefore, an object of the present invention to provide an apparatus for supplying an internal voltage with the characteristic of optimizing current consumption based on an operation mode of semiconductor memory device.

In accordance with an aspect of the present invention, there is provided an apparatus for supplying an internal voltage, comprising: a comparison unit for comparing a reference voltage with an internal reference voltage to output a driving signal based on the comparison result; an internal voltage providing unit for providing the internal voltage according to the current value of the driving signal; a first biasing unit for providing a first bias current to the comparison unit according to the reference voltage; and a second biasing unit for providing a second bias current to the comparison unit according to a standby operation mode.

### BRIEF DESCRIPTION OF THE DRAWINGS

The above and other objects and features of the present invention will become better understood with respect to the following description of the specific embodiments given in conjunction with the accompanying drawings, in which:

FIG. 1 is a schematic diagram illustrating a conventional apparatus for supplying an internal voltage for use in memory device; and

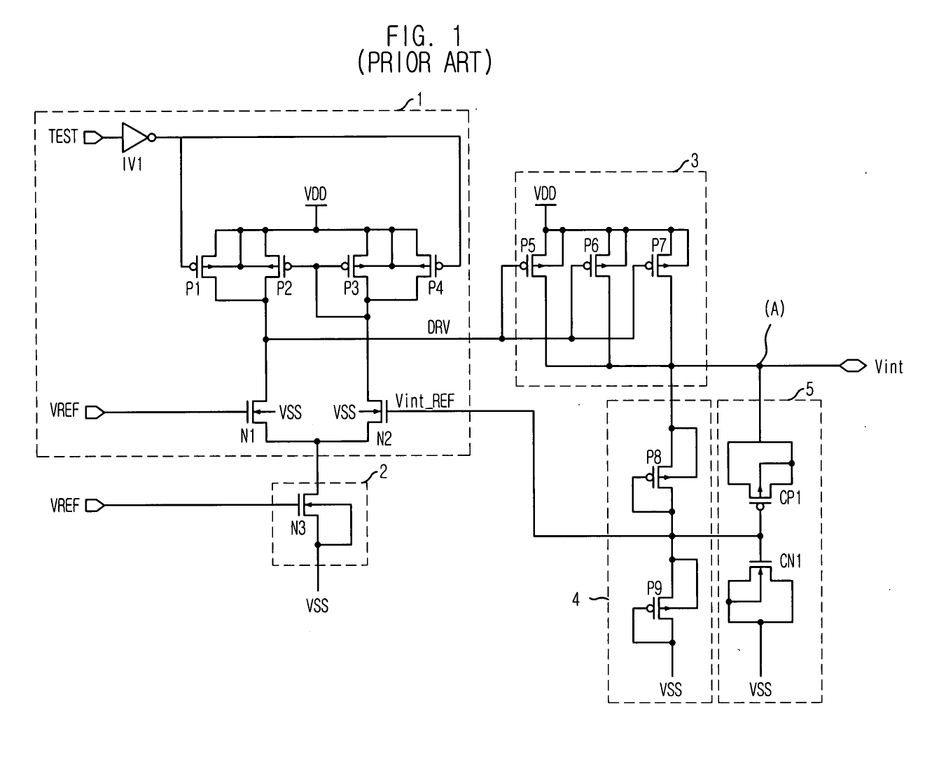

FIG. 2 is a schematic diagram illustrating an apparatus for supplying an internal voltage in accordance with a specific embodiment of the present invention.

### DETAILED DESCRIPTION OF THE INVENTION

An apparatus for supplying an internal voltage in accordance with specific embodiments of the present invention will be described in detail with reference to the accompanying drawings.

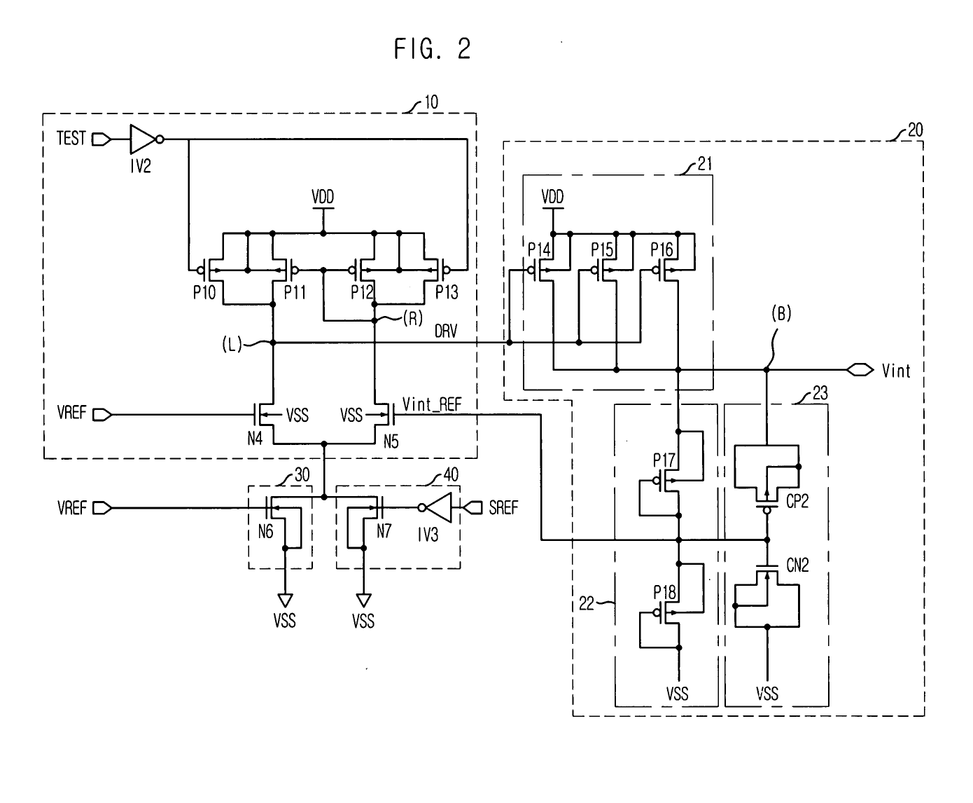

FIG. 2 is a schematic diagram illustrating an apparatus for supplying an internal voltage in accordance with a specific embodiment of the present invention.

The specific embodiment of the present invention includes: a comparison unit 10; an internal voltage providing unit 20; a first biasing unit 30; and a second biasing unit 40.

The comparison unit 10 includes an inverter IV2, PMOS transistors P10 to P13 wherein PMOS transistors P11 and P12 forms a current mirror, and NMOS transistors N4 and N5. The comparison unit 10 compares a reference voltage VREF with an internal reference voltage Vint_REF to output a driving signal DRV.

Herein, a reference circuit using band gap type or widlar type, although not illustrated, is used to generate a uniform level of the reference voltage VREF, regardless of a variation of an external power, temperature and process.

The reference voltage VREF maintaining uniform level regardless of a variation of an external power, temperature and process is inputted into a gate of the NMOS transistor N4.

The internal voltage providing unit 20 includes a current control unit 21; a load unit 22 and a capacitor unit 23.

The current control unit 21 includes PMOS transistors P14 to P16 connected in parallel between a supply terminal of an external voltage VDD and an output terminal of an internal voltage Vint, wherein the driving signal DRV is inputted at each gate of the PMOS transistors P14 to P16.

The load unit 22 connected between the output terminal of the internal voltage Vint and a supply terminal of the ground voltage VSS includes PMOS transistors P17 and P18, wherein each gate of PMOS transistors P17 and P189 is connected to each drain of the same for performing an operation as a diode.

Also, the capacitor unit 23 connected between the output terminal of the internal voltage Vint and a supply terminal of the ground voltage VSS includes a first capacitor CP2 made using a PMOS transistor and a second capacitor CN2 made using an NMOS transistor for maintaining the voltage levels of the internal voltage and the internal reference voltage Vint_REF.

The first biasing unit 30 connected between the comparison unit 10 and a ground voltage VSS includes an NMOS transistor N6, wherein the reference VREF is inputted at the gate of the NMOS transistor N6. The NMOS transistor N6 is turned on while the reference VREF provides a stable reference voltage in order to control a bias state of the comparison unit 10.

The second biasing unit 40 connected in parallel with the first biasing unit 30 between the comparison unit 10 and a terminal of a ground voltage VSS includes NMOS transistors N7 and an inverter IV3. The inverter IV3 inverts a self refresh signal SREF and outputs into a gate of the NMOS transistor N7.

The NMOS transistor N7 is turned on when the self refresh signal SREF is inactivated, and provides a bias point to the comparison unit 10. On the other hand, the NMOS transistor N7 is turned off when the self refresh signal SREF is activated, and prevents unnecessary current from the comparison unit 10 to the supply terminal of the ground voltage VSS through the second biasing unit 40.

The NMOS transistors N6 and N7 of the present invention are each formed to be half the size of NMOS transistor N3 of the conventional apparatus. During the self refresh mode, only one of the NMOS transistors N6 and N7 are turned on, resulting in reduced standby current consumption and a rapidly controllable response characteristic of the comparison unit 10. Herein, a size of the NMOS transistors N6 and N7 is considered adequate for an operation environment of a memory device.

An operation process of the specific embodiment of the present invention with the above configuration is described below.

A test signal TEST is low and disabled during a normal operation mode. Accordingly, a current mirror operates normally during the normal operation mode, and generates an internal voltage double the amount of the reference voltage VREF to drive current. Herein, the reference voltage VREF for generating the internal voltage is generally required to be set up before reaching a power up level.

On the other hand, if the test signal TEST is high and enabled, the PMOS transistors P10 to P13 are turned on, and a node (L) and a node (R) reach a supply voltage VDD level, and thus the current mirror operation is disabled.

The operation process of the specific embodiment of the present invention is described below in more detail.

When a power up signal which acknowledges circuit initialization is enabled and the supply voltage reaches a level capable of performing normal operations, a uniform current is supplied through the PMOS transistor P10 and P11.

Herein, when the reference voltage VREF is supplied into a gate terminal of the NMOS transistor N5 and the transistor is enabled, then the comparison unit 10 operates.

Afterwards, the comparison unit 10 compares the reference voltage VREF and the internal reference voltage Vint_REF. If the internal reference voltage Vint_REF is lower than the reference voltage VREF, current in the node (L) is decreased. Accordingly, an electric potential of the driving signal DRV is decreased, and thus the PMOS transistor P14 to P16 are turned on, resulting in a larger amount of current being supplied into the output node (B).

Such operations continue until the reference voltage VREF and an electric potential of the internal reference voltage Vint_REF become identical by a sensing operation of the current mirror. Accordingly, the electric potential of the internal voltage Vint becomes two times higher than the internal reference voltage Vint REF due to a distribution effect of the PMOS transistors P17 and P18. Also, because a small amount of current flows due to the PMOS transistors P17 and P18 operating as diodes, the internal voltage Vint is prevented from diffusion.

At this time, when there is a periodic current consumption in the output node (B), the internal voltage Vint is generally required to recover back to the original level as fast as possible. Thus, in an active mode, the NMOS transistors N6 and N7 are all turned on and supply normal current to the comparison unit 10.

On the other hand, the self refresh signal SREF is activated during a self refresh operation mode when there is any current consumption in the output node (B). Accordingly, current supplied to the comparison unit 10 can be decreased by turning the NMOS transistor N7 off.

Although the specific embodiment of the present invention described utilizing one activated transistor N7, the specific embodiment of the present invention may be applied with two or more enable transistors. By turning on and off the transistors, the response characteristic and the amount of standby current can be controlled.

In accordance with the specific embodiment of the present invention, an internal voltage driving circuit, which converts an external supply power into a low electric potential, capable of reducing the amount of standby current consumed in a current mirror during a self refresh mode is provided.

The present application contains subject matter related to the Korean patent application No. KR 2005-0048378, filed in the Korean Patent Office on Jun. 7, 2005, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

We claim:

1. An apparatus for supplying an internal voltage, comprising:
a comparison means for comparing a reference voltage with an internal reference voltage to output a driving signal based on the comparison result;
an internal voltage providing means for providing the internal voltage according to a current value of the driving signal;
a first biasing means for providing a first bias current to the comparison means according to the reference voltage; and
a second biasing means for providing a second bias current to the comparison means according to a standby operation mode.

2. The apparatus as recited in claim 1, wherein the standby operation mode is a self refresh mode.

3. The apparatus as recited in claim 1, wherein the second biasing means includes:
an inverter for inverting an enabled self refresh signal during the self refresh mode; and
a NMOS transistor for providing the second current, wherein an output of the inverter is inputted at the gate of the NMOS transistor.

4. The apparatus as recited in claim 1, wherein a second biasing means includes a plurality of second biasing units, each enabled in response to an operation mode of a semiconductor device for providing the second biasing current to the comparison means, the second biasing current varying based on the operation mode.

5. The apparatus as recited in claim 1, wherein the first biasing means is turned off and the second biasing means is turned on during the self refresh mode.

6. The apparatus as recited in claim 5, wherein the first biasing means and the second biasing means are both turned on during a normal mode.

7. The apparatus as recited in claim 1, wherein the comparison means outputs a driving signal if a reference voltage and an internal reference voltage are not the same.

8. An apparatus for supplying an internal voltage, comprising:
a comparator configured to compare a reference voltage with an internal reference voltage to output a driving signal based on the comparison result;
a circuit configured to provide the internal voltage according to a current value of the driving signal;
a first biasing circuit configured to for provide a first bias current to the comparator according to the reference voltage; and
a second biasing circuit configured to provide a second bias current to the comparator according to a standby operation mode.
